(19) United States
(12) Patent Application Publication
(10) Pub. No.: US 2011/0024305 A1
(43) Pub. Date: Feb. 3, 2011

(54) Differential Amplifier Sensor Architecture for Increased Sensing Selectivity

(76) Inventor: Matthew H. Ervin, (US)

Correspondence Address: U S ARMY RESEARCH LABORATORY;ATTN: RDRL-LOC-I, 2800 POWDER MILL RD, ADELPHI, MD, 20783-1197, US

(21) Appl. No.: 12/827,131

(22) Filed: Jun. 30, 2010

Related U.S. Application Data
(60) Provisional application No. 61/229,540, filed on Jul. 29, 2009.

(51) Int. Cl. G01N 27/26; H03F 3/45

(52) U.S. Cl. 205/775; 330/253; 204/406

(57) ABSTRACT

A differential amplifier and method of sensing includes a first carbon nanotube field effect transistor (CNTFET) that selectively detects an analyte from an environment comprising analytes and nonspecific interferences, and produces a first signal associated with the detected analyte and any nonspecific interferences; a second CNTFET adjacent to the first CNTFET, wherein the second CNTFET detects the nonspecific interferences of the environment, and produces a second signal associated with the detected nonspecific interferences; and means for generating a differential output signal using the first signal and the second signal as input, wherein the differential output signal is completely devoid of the second signal.

### CROSS REFERENCE TO RELATED APPLICATION

This application claims the benefit of U.S. Provisional Patent Application No. 61/229,540 filed on Jul. 29, 2009, the complete disclosure of which, in its entirety, is herein incorporated by reference.

### GOVERNMENT INTEREST

The embodiments herein may be manufactured, used, and/or licensed by or for the United States Government without the payment of royalties thereon.

### BACKGROUND OF THE INVENTION

1. Technical Field

The embodiments herein generally relate to chemical and biochemical sensing technologies, and, more particularly, to biomolecular sensors used for sensing complex and dynamic environments.

2. Description of the Related Art

In the past differential amplifiers have been used to demonstrate the differential sensing of ammonia using nonselective sensors and a physical barrier between the reference sensor and the ammonia. In addition, while previously known biosensing provides selectivity, the conventional techniques may not be sufficient to produce acceptably low false positive rates for military applications. One issue for instance is weak binding between slightly mismatched probes and analytes, or there may be nonspecific binding where the analyte binds to the sensor without regard for the probe functional group.

### BRIEF SUMMARY OF THE INVENTION

In view of the foregoing, an embodiment herein provides a differential amplifier comprising a first carbon nanotube field effect transistor (CNTFET) that selectively detects an analyte from an environment comprising analytes and nonspecific interferences, and produces a first signal associated with the detected analyte and any nonspecific interferences; a second CNTFET adjacent to the first CNTFET, wherein the second CNTFET detects the nonspecific interferences of the environment, and produces a second signal associated with the detected nonspecific interferences; and means for generating a differential output signal using the first signal and the second signal as input, wherein the differential output signal is completely devoid of the second signal. In one embodiment, the differential amplifier further comprises a first voltage divider comprising the first CNTFET and a first electronic trimmer device such as a trimpot; and a second voltage divider comprising the second CNTFET and a second electronic trimmer device such as a trimpot, wherein the second voltage divider shares an input voltage with the first voltage divider, wherein the differential output signal comprises an output voltage measured between the first voltage divider and the second voltage divider at a location where the first electronic trimmer device connects to the first CNTFET and where the second electronic trimmer device connects to the second CNTFET.

In another embodiment, each of the first CNTFET and the second CNTFET is chemically functionalized, and wherein the first CNTFET is functionalized differently than the second CNTFET. The differential amplifier may further comprise an electronic trimmer device such as a trimpot operatively connected to an output of each of the first CNTFET and the second CNTFET. Preferably, the analytes comprise known analytes and unknown analytes, and wherein the differential output signal selectively identifies detected known analytes from detected unknown analytes.

Another aspect of the embodiments herein includes a sensing system of an environment comprising known and unknown analytes and interferents, the system comprising a first sensor that selectively detects a target analyte from the environment and non-selectively detects any known or unknown interferents from the environment, and produces a first signal; a second sensor adjacent to the first sensor, wherein the second sensor non-selectively detects the interferents of the environment and produces a second signal; and means for generating a differential output signal using the first signal and the second signal as input, wherein the differential output signal is completely devoid of the second signal, and wherein the differential output signal selectively identifies a detected known analyte from the detected unknown analytes and nonspecific interference species. In one embodiment, each of the first sensor and the second sensor comprise any of a CNTFET, a chemical field effect transistor, and a chemresistor.

In one embodiment, the second sensor senses the nonselective interferents similarly to the first sensor so that this component of the combined signal can be subtracted out. Also, in another embodiment, the second sensor nonselectively, and therefore less sensitively, detects the desired analyte. In this case, the subtraction of the second sensor signal from the first sensor signal diminishes the analyte's signal, but the signal (desired analyte signal) to noise (the interfering signals) is still improved.

In one embodiment, the system further comprises a first voltage divider comprising the first sensor and a first electronic trimmer device such as a trimpot; and a second voltage divider comprising the second sensor and a second electronic trimmer device such as a trimpot, wherein the second voltage divider shares an input voltage with the first voltage divider, wherein the differential output signal comprises an output voltage measured between the first voltage divider and the second voltage divider at a location where the first electronic trimmer device connects to the first sensor and where the second electronic trimmer device connects to the second sensor.

In another embodiment, each of the first sensor and the second sensor is chemically functionalized, and wherein the first sensor is functionalized differently than the second sensor. The system may further comprise an electronic trimmer device operatively connected to an output of each of the first sensor and the second sensor. Moreover, the system may further comprise means for measuring the differential output signal. Preferably, the first sensor and the second sensor form a differential amplifier.

Another aspect of the embodiments herein includes a method of sensing an environment comprising analytes and nonspecific interferents, the method comprising selectively detecting an analyte from the environment using a first CNTFET; producing a first signal associated with the detected analyte and any nonspecific interferences from the first CNTFET; detecting the nonspecific interferences from the environment using a second CNTFET; producing a second signal associated with the detected nonspecific interferences from the second CNTFET; subtracting the second signal from the first signal; and generating a differential output signal using the first signal and the second signal as input, wherein the differential output signal is completely devoid of the second signal.

In one embodiment, the method further comprises chemically functionalizing each of the first CNTFET and the second CNTFET, wherein the first CNTFET is functionalized differently than the second CNTFET. In another embodiment, the method further comprises positioning an electronic trimmer device such as a trimpot to an output of each of the first CNTFET and the second CNTFET. In another embodiment, the first CNTFET and a first electronic trimmer device such as a trimpot form a first voltage divider, wherein the second CNTFET and a second electronic trimmer device such as a trimpot form a second voltage divider, wherein the second voltage divider shares an input voltage with the first voltage divider, and wherein the differential output signal comprises an output voltage measured between the first voltage divider and the second voltage divider at a location where the first electronic trimmer device connects to the first CNTFET and where the second electronic trimmer device connects to the second CNTFET. Preferably, the analytes comprise known analytes and unknown analytes, and wherein the differential output signal selectively identifies detected known analytes from detected unknown analytes.

These and other aspects of the embodiments herein will be better appreciated and understood when considered in conjunction with the following description and the accompanying drawings. It should be understood, however, that the following descriptions, while indicating preferred embodiments and numerous specific details thereof, are given by way of illustration and not of limitation. Many changes and modifications may be made within the scope of the embodiments herein without departing from the spirit thereof, and the embodiments herein include all such modifications.

### BRIEF DESCRIPTION OF THE SEVERAL VIEWS OF THE DRAWINGS

The embodiments herein will be better understood from the following detailed description with reference to the drawings, in which:

FIG. 1A is a schematic diagram illustrating a sensing system according to an embodiment herein;

FIG. 1B is a circuit diagram illustrating a differential amplifier according to an embodiment herein;

FIG. 2 is a cross-sectional diagram illustrating a semiconductor device according to an embodiment herein; and

FIG. 3 is a flow diagram illustrating a method according to an embodiment herein.

### DETAILED DESCRIPTION OF THE INVENTION

The embodiments herein, and the various features and advantageous details thereof, are explained more fully with reference to the non-limiting embodiments that are illustrated in the accompanying drawings and detailed in the following description. Descriptions of well-known components and processing techniques are omitted so as to not unnecessarily obscure the embodiments herein. The examples used herein are intended merely to facilitate an understanding of ways in which the embodiments herein may be practiced and to further enable those of skill in the art to practice the embodiments herein. Accordingly, the examples should not be construed as limiting the scope of the embodiments herein.

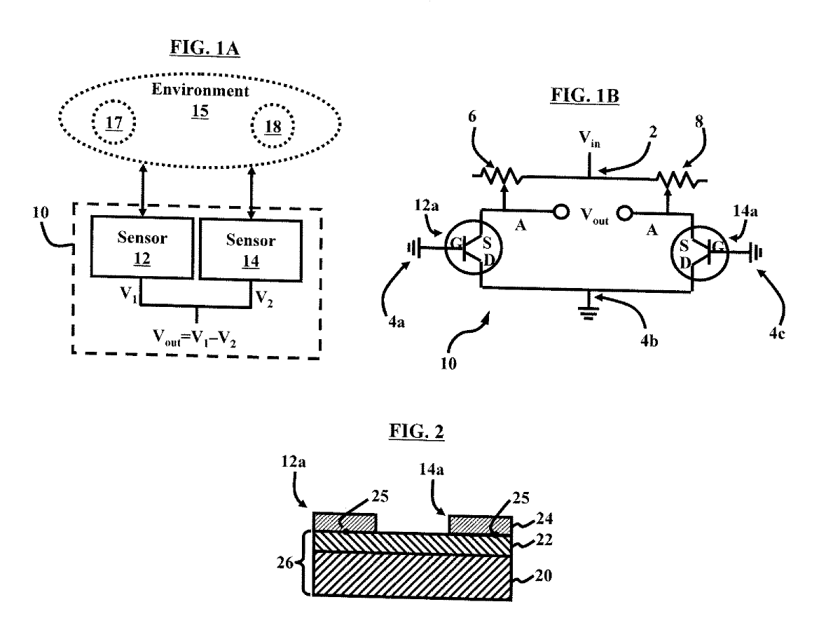

The embodiments herein provide a differential amplifier sensor architecture used for improving sensor selectivity. Referring now to the drawings, and more particularly to FIGS. 1A through 3, where similar reference characters denote corresponding features consistently throughout the figures, there are shown preferred embodiments.

As shown in FIGS. 1A and 1B, the embodiments herein provide two very similar sensors 12, 14 in a differential amplifier configuration 10; one sensor 12 does not have to discriminate against a wide range of interfering signals 18 and the output (V₂) from the other sensor 14 is subtracted from the output (V₁) of the first sensor 12. The first sensor 12 is selective to the analyte 17 and may or may not discriminate against interfering signals 18. The second sensor 14 does not selectively sense the analyte 17 and it discriminates against interfering signals 18 to the same degree as the first sensor 12. Accordingly, by subtracting the signal from the second sensor 14 from the signal of the first sensor 12, the signal due to the analyte 17 can be measured without contributions from interfering signals 18. This produces enhanced sensor selectivity in applications such as chemical sensing for chemical, biological agents, explosives, toxic industrial chemicals, and in biochemical and medical assays, for example. The use of a differential amplifier sensor architecture 10 improves sensor selectivity. In one embodiment, the sensors 12, 14 are configured as carbon nanotube field effect transistors (CNTFETs) 12a, 14a that use CNTs as the device channel in a source (S), drain (D), and gate (G) configuration. The CNTFETs 12a, 14a are used as both the transistors in the differential amplifier 10 as well as chemical sensing elements 12, 14. Chemical functionalization of the CNTFETs 12a, 14a results in selective sensing.

By functionalizing the two CNTFETs 12a, 14a differently with respect to one another, one CNTFET 12a can be tailored to selectively sense an analyte 17, and the other CNTFET 14a can be used as a reference sensor 14 to compensate for a wide range of interfering signals 18 when the two CNTFET outputs (V₁, V₂) are subtracted to produce an output voltage (Vₒᵤₜ=V₁−V₂). In this way, many interfering events 18 are discriminated against to yield robust and selective sensing in complex and dynamic environments 15.

The sensors 12, 14 are configured as amperometric chemical/biological CNTFET nanosensors that are sensitive since all of the CNT atoms are able to interact closely with the environment 15 according to one embodiment herein. Most CNT sensors such as those known in the art are examples of nonselective sensing using bare CNTs. Such sensors are either basic investigations into sensing physics or they are applied to the development of small molecule sensors for use in well-defined environments. However, functionalized CNTFET biomolecule sensors 12, 14 provide a versatility of operation. The sensors 12, 14 use little power, are lightweight, and low cost compared to conventional sensors in order to facilitate wide distribution either in unattended networks or by equipping individuals with sensor arrays (e.g., soldiers in a military application). The embodiments herein may be utilized in various applications such as, but not limited to, detection of water/food borne pathogens, chemical/biological agents, explosives, toxic industrial chemicals, etc. as well as for sensing used for chemical hygiene, medical diagnostics, and pharmaceuticals, etc.

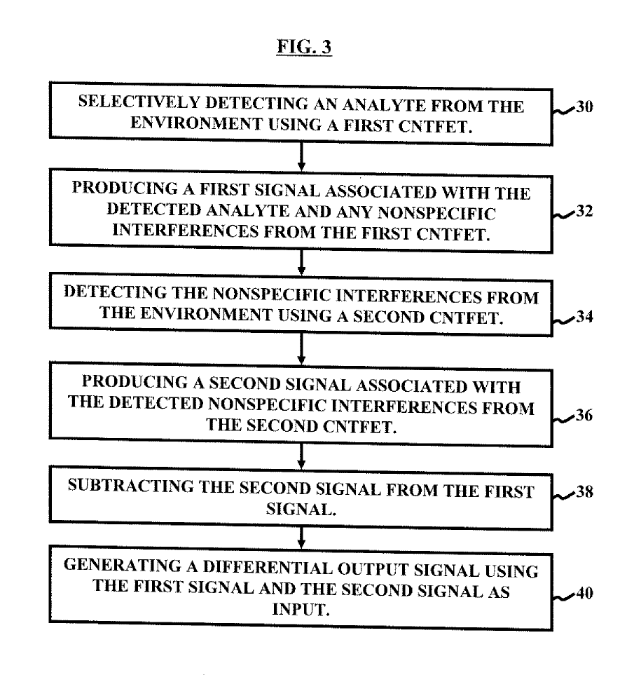

An example of the fabrication of the differential amplifier 10 is illustrated in FIG. 2, with respect to FIGS. 1A and 1B. In one embodiment, the CNTFETs 12a, 14a are fabricated by spin coating commercially obtained single-wall CNT solutions (e.g., approximately 400 mg/L in acetone) containing CNTs 25 onto an approximately 0.25-0.5 micrometer thick insulator layer 22 (e.g., silicon dioxide, etc.) on a conductive semiconductor wafer 20 (e.g., silicon, etc.). The conductive wafer 20 serves as a backgate for the devices 12a, 14a. Standard photolithography can be performed to deposit Cr/Au contacts 24 onto the sparsely CNT coated surface resulting in a single to a few CNTs 25 per device 12a, 14a. The channel widths between the source (S) and drain (D) contacts are approximately 5 micrometers or less. The photolithography mask (not shown) patterns two sets of sensor electrodes 12, 14, which are separated on the die 26 so that they can be chemically functionalized differently.

Measurement of the differential output of two sensors 12, 14 can be accomplished in a number of ways. Initially, I_{sd}, the source drain current, of two devices 12a, 14a is measured simultaneously using a semiconductor parameter analyzer with the two sensor outputs (V₁, V₂) being subtracted using software. In one embodiment, the output (V₂) of device 14a is normalized to device 12a before subtraction in order to compensate for differences between the devices 12a, 14a.

In one embodiment, a differential amplifier 10 is assembled on a breadboard (not shown) with the actual hardware subtracted output being measured by a chart recorder monitoring the differential amplifier output voltage as a function of time. The differential amplifier circuit 10 of FIG. 1B provides two voltage dividers that share an input voltage (Vᵢₙ) (e.g., approximately 0.25 V) at one end 2 and are grounded at the other end 4a, 4b, 4c. Each voltage divider includes an electronic trimmer device 6, 8 such as a variable resistor that is approximately 0-1 MΩ and a CNTFET 12a, 14a, which has a typical resistance of hundreds of kΩ. The differential amplifier output Vₒᵤₜ is then a voltage measured between the two voltage dividers at the point A where the electronic trimmer devices 6, 8 are connected to the CNTFETs 12a, 14a. By adjusting the electronic trimmer devices 6, 8, one can zero the [symbol] .

In order to overcome the limitations of the conventional solutions, the differential amplifier architecture 10 provided by the embodiments herein enhances selectivity between similar analytes 17 as well as discriminating against nonspecific interferents 18. The first sensor 12, the signal sensor, is functionalized to selectively detect an analyte 17. The second sensor 14, the background sensor, is similarly functionalized, but is not tailored to detect the analyte 17 (e.g., a slight change in the functional group sequence). The similarity between the signal and background sensors 12, 14, respectively, results in similar responses to any interferents 18. The signal sensor 12, in addition to sensing the interferents 18, is more sensitive to the analyte 17. The background sensor output V₂ is subtracted from the signal sensor output V₁ so as to remove any background signals and leave only the analyte signal at the differential amplifier output Vₒᵤₜ. This significantly reduces false positives when sensing in complex and changing environments. The differential amplifier 10 allows one to discriminate against anticipated as well as unanticipated/unknown interferent species 18. In this way, the sensor system (i.e., architecture 10) selectivity is enhanced in hardware (the differential amplifier circuit 10) without the overhead of computational processing; an improvement over conventional systems. An additional feature to conducting the background subtraction in hardware is that the process occurs continuously in real time. In many implementations, a fast and accurate response may be more important than sensitivity depending upon how dynamic the threat environment is.

No functionalization of CNTFETs 12a, 14a is required for sensing ammonia, nitric oxide, and similar electron donating or withdrawing molecules, for example. Experimentally, the signal sensor 12 can be exposed to ammonia vapor in air (ppm level) while the background sensor 14 is only exposed to the air. Since the ammonia binds strongly to the bare CNTs 25, the sensor 12 is slow to refresh after removal of the ammonia.

In another example, background subtraction using a selective sensing technique is provided. Here, the CNTFETs 12a, 14a are functionalized with polypeptides Trypsin sensing experiments can be performed using a functionalization process where CNTFET 12a is coated on a die 26 with poly-L-lysine (PLL) (not shown). In this example, trypsin is the analyte 17. Trypsin is a protease which cleaves polypeptides wherever there is a lysine or arginine peptide in the sequence. Hence, PLL is readily cleaved by the trypsin enzyme, while PLH is not. Cleavage of the PLL makes it soluble, thus removing its electrostatic gating effect on the CNTFET 12a (lysine and histidine are positively charged at neutral pH). The PLL is deposited using an approximately 0.005% (w/v) solution of PLL dissolved in an approximately 10 mM TRIS/50 mM NaCl, pH 7.2 buffer solution. An approximately 3 microliter droplet of this solution is deposited onto the CNTFET 12a for approximately 200 seconds before it is removed using dry nitrogen, for example. The functionalized CNTFET 12a is then briefly rinsed in a beaker of the buffer solution leaving a thin coating of PLL. The buffer is then replaced by a trypsin in buffer solution from 1050-1250 seconds, followed by infusion of fresh buffer solution. A number of infusions of fresh buffer solution later in the measurement (e.g., >2000 seconds) can also induce changes in the sensor outputs V₁, V₂. The CNTFET 14a on the other side of the die 14a is similarly functionalized using poly-L-histidine (PLH). Since trypsin cleaves peptide bonds at lysine residues, but not at histidine residues, the PLL coated CNTFET 12a senses the trypsin via the dissolution of the PLL coating while the PLH coated CNTFET 14a does not.

FIG. 3, with reference to FIGS. 1A through 2, is a flow diagram illustrating a method of sensing an environment 15 comprising analytes 17 and nonspecific interferences 18, the method comprising selectively detecting (30) an analyte 17 from the environment 15 using a first CNTFET 12a; producing (32) a first signal V₁ associated with the detected analyte 17 and any nonspecific interferences 18 from the first CNTFET 12a; detecting (34) the nonspecific interferences 18 from the environment 15 using a second CNTFET 14a; producing (36) a second signal V₂ associated with the detected nonspecific interferences 18 from the second CNTFET 14a; subtracting (38) the second signal V₂ from the first signal V₁; and generating (40) a differential output signal Vₒᵤₜ using the first signal V₁ and the second signal V₂ as input, wherein the differential output signal Vₒᵤₜ is completely devoid of the second signal V₂.

In one embodiment, the method further comprises wire bonding the first CNTFET 12a to the second CNTFET 14a. In another embodiment, the method further comprises chemically functionalizing each of the first CNTFET 12a and the second CNTFET 14a with polypeptides or other selectively interacting (bonding, cleaving, reacting, conformational change inducing, etc.) molecules such as DNA, PNA, and antibodies, etc., which will result in a change in the FET conductances, wherein the first CNTFET 12a is functionalized differently than the second CNTFET 14a. In another embodiment, the method further comprises positioning an electronic trimmer device 6, 8 to an output of each of the first CNTFET 12a and the second CNTFET 14a, wherein the electronic trimmer device 6, 8 balances signals V₁, V₂ when the sensors 12, 14 are not well matched. In another embodiment, the first CNTFET 12a and a first electronic trimmer device 6 form a first voltage divider, wherein the second CNTFET 14a and a second electronic trimmer device 8 form a second voltage divider, wherein the second voltage divider shares an input voltage Vᵢₙ with the first voltage divider, and wherein the differential output signal Vₒᵤₜ comprises an output voltage measured between the first voltage divider and the second voltage divider at a location A where the first electronic trimmer device 6 connects to the first CNTFET 12a and where the second electronic trimmer device 8 connects to the second CNTFET 14a. Preferably, the analytes 17 comprise known analytes and unknown analytes, and wherein the differential output signal Vₒᵤₜ selectively identifies detected known analytes from detected unknown analytes.

Generally, the embodiments herein provide two similarly functionalized chemically sensitive CNTFETs 12a, 14a that act as both the chemical sensors and active elements in a differential amplifier 10 in order to increase the sensing selectivity of the circuit 10. The transistors are deployed for use in background signal subtraction.

Unconventionally, the sensors 12, 14 can be functionalized for the specific application/analyte desired, which may require some development work for each application. Furthermore, those skilled in the art may find it unconventional to use the same devices 12a, 14a as both the sensing element and the active elements in a differential amplifier circuit 10 as this is not conventionally done in the art.

The foregoing description of the specific embodiments will so fully reveal the general nature of the embodiments herein that others can, by applying current knowledge, readily modify and/or adapt for various applications such specific embodiments without departing from the generic concept, and, therefore, such adaptations and modifications should and are intended to be comprehended within the meaning and range of equivalents of the disclosed embodiments. It is to be understood that the phraseology or terminology employed herein is for the purpose of description and not of limitation. Therefore, while the embodiments herein have been described in terms of preferred embodiments, those skilled in the art will recognize that the embodiments herein can be practiced with modification within the spirit and scope of the appended claims.

What is claimed is:

1. A differential amplifier comprising:
a first carbon nanotube field effect transistor (CNTFET) that selectively detects an analyte from an environment comprising analytes and nonspecific interferences, and produces a first signal associated with the detected analyte and any nonspecific interferences;
a second CNTFET adjacent to said first CNTFET, wherein said second CNTFET detects said nonspecific interferences of said environment, and produces a second signal associated with the detected nonspecific interferences; and
means for generating a differential output signal using said first signal and said second signal as input, wherein said differential output signal is completely devoid of said second signal.

2. The differential amplifier of claim 1, further comprising:
a first voltage divider comprising said first CNTFET and a first electronic trimmer device; and
a second voltage divider comprising said second CNTFET and a second electronic trimmer device, wherein said second voltage divider shares an input voltage with said first voltage divider,
wherein said differential output signal comprises an output voltage measured between said first voltage divider and said second voltage divider at a location where said first electronic trimmer device connects to said first CNTFET and where said second electronic trimmer device connects to said second CNTFET.

3. The differential amplifier of claim 2, wherein said first electronic trimmer device and said second electronic trimmer device comprise a trimpot.

4. The differential amplifier of claim 1, wherein each of said first CNTFET and said second CNTFET is chemically functionalized, and wherein said first CNTFET is functionalized differently than said second CNTFET.

5. The differential amplifier of claim 1, further comprising an electronic trimmer device operatively connected to an output of each of said first CNTFET and said second CNTFET.

6. The differential amplifier of claim 1, wherein said analytes comprise known analytes and unknown analytes, and wherein said differential output signal selectively identifies detected known analytes from detected unknown analytes.

7. A sensing system of an environment comprising known and unknown analytes and interferents, said system comprising:
a first sensor that selectively detects analytes and any known or unknown interferents from said environment, and produces a first signal;
a second sensor adjacent to said first sensor, wherein said second sensor non-selectively detects said interferents of said environment and produces a second signal; and
means for generating a differential output signal using said first signal and said second signal as input, wherein said differential output signal is completely devoid of said second signal,
wherein said differential output signal selectively identifies a detected known analyte from the detected unknown analytes and nonspecific interference species.

8. The system of claim 7, wherein each of said first sensor and said second sensor comprises any of a carbon nanotube field effect transistor (CNTFET), a chemical field effect transistor, and a chemresistor.

9. The system of claim 7, further comprising:
a first voltage divider comprising said first sensor and a first electronic trimmer device; and
a second voltage divider comprising said second sensor and a second electronic trimmer device, wherein said second voltage divider shares an input voltage with said first voltage divider,
wherein said differential output signal comprises an output voltage measured between said first voltage divider and said second voltage divider at a location where said first electronic trimmer device connects to said first sensor and where said second electronic trimmer device connects to said second sensor.

10. The system of claim 9, wherein said first electronic trimmer device and said second electronic trimmer device comprise a trimpot.

11. The system of claim 7, wherein each of said first sensor and said second sensor is chemically functionalized, and wherein said first sensor is functionalized differently than said second sensor.

12. The system of claim 7, further comprising an electronic trimmer device operatively connected to an output of each of said first sensor and said second sensor.

13. The system of claim 7, further comprising means for measuring said differential output signal.

14. The system of claim 7, wherein said first sensor and said second sensor form a differential amplifier.

15. A method of sensing an environment comprising analytes and nonspecific interferences, said method comprising:
selectively detecting an analyte from said environment using a first carbon nanotube field effect transistor (CNTFET);
producing a first signal associated with the detected analyte and any nonspecific interferences from said first CNTFET;
detecting said nonspecific interferences from said environment using a second CNTFET;
producing a second signal associated with the detected nonspecific interferences from said second CNTFET;
subtracting said second signal from said first signal; and
generating a differential output signal using said first signal and said second signal as input, wherein said differential output signal is completely devoid of said second signal.

16. The method of claim 15, further comprising chemically functionalizing each of said first CNTFET and said second CNTFET, wherein said first CNTFET is functionalized differently than said second CNTFET.

17. The method of claim 15, further comprising positioning an electronic trimmer device to an output of each of said first CNTFET and said second CNTFET.

18. The method of claim 17, wherein said electronic trimmer device comprises a trimpot.

19. The method of claim 18, wherein said first CNTFET and a first electronic trimmer device form a first voltage divider, wherein said second CNTFET and a second electronic trimmer device form a second voltage divider, wherein said second voltage divider shares an input voltage with said first voltage divider, and wherein said differential output signal comprises an output voltage measured between said first voltage divider and said second voltage divider at a location where said first electronic trimmer device connects to said first CNTFET and where said second electronic trimmer device connects to said second CNTFET.

20. The method of claim 15, wherein said analytes comprise known analytes and unknown analytes, and wherein said differential output signal selectively identifies detected known analytes from detected unknown analytes.
